(19) United States
(12) Patent Application Publication
(10) Pub. No.: US 2025/0183909 A1
(43) Pub. Date: Jun. 5, 2025

(54) CIRCUIT AND METHOD FOR MEASURING AND CORRECTING INTERLEAVING SPUR OF AT LEAST ONE TIME-INTERLEAVED DIGITAL-TO-ANALOG CONVERTER IN DELTA-SIGMA ANALOG-TO-DIGITAL CONVERTER

(71) Applicant: MEDIATEK INC., Hsinchu City (TW)

(72) Inventors: Yunzhi Dong, San Jose, CA (US); Nathan Egan, San Jose, CA (US); Timothy Perrin Fisher-Jeffes, Cambridge (GB)

(73) Assignee: MEDIATEK INC., Hsinchu City (TW)

(21) Appl. No.: 18/963,723

(22) Filed: Nov. 28, 2024

Related U.S. Application Data
(60) Provisional application No. 63/605,623, filed on Dec. 4, 2023.

(51) Int. Cl. H03M 3/00

(52) U.S. Cl. CPC H03M 3/37; H03M 3/328; H03M 3/464

(57) ABSTRACT

A measuring circuit measures an interleaving (IL) spur of at least one time-interleaved digital-to-analog converter (DAC) included in a delta-sigma (DS) analog-to-digital converter (ADC). The measuring circuit includes a dither tone generator circuit and a digital signal processing circuit. The dither tone generator circuit generates a dither tone with a pre-defined tone frequency, and injects the dither tone to the DS ADC. The digital signal processing circuit processes a digital output of the DS ADC with the dither tone injected, to generate a measurement result of the IL spur that is induced by the at least one time-interleaved DAC due to the injected dither tone.

### CROSS REFERENCE TO RELATED APPLICATIONS

This application claims the benefit of U.S. Provisional Application No. 63/605,623, filed on Dec. 4, 2023. The content of the application is incorporated herein by reference.

### BACKGROUND

The present invention relates to an analog-to-digital converter design, and more particularly, to a circuit and method for measuring and correcting an interleaving spur of at least one time-interleaved digital-to-analog converter included in a delta-sigma analog-to-digital converter.

Continuous-time (CT) delta-sigma (DS) analog-to-digital converters (ADCs) are widely used in wireless transceivers. Taking band-pass CTDS ADCs for example, they use resonator-based loop filter along with accurate feedback digital-to-analog converters (DACs) to shape quantization noise of the quantizer in the desired band at a chosen carrier frequency. The performance of feedback DACS determines the performance of the ADC as its accuracy directly maps to the accuracy of the ADC. Specifically, noise, nonlinearity and other errors introduced by feedback DACs will be directly added to the ADC output. Time-interleaved DACs may be used to implement high-speed feedback DACs in the CTDS ADC. For example, a double-data-rate (DDR) DAC updates its output (current) at both rising edge and falling edge, which effectively boosts DAC sampling rate by 2×. However, the use of time-interleaved DAC (e. g., DDR DAC) to significantly increase the DAC sampling rate of a conventional DAC is not without its challenges. These challenges stem from the increased complexity required to create multiple identical channels and sub-ADCs. The channels must have identical gain, bandwidth, sample timing and DC offset as well as identical Sub-ADC performance. Any mismatch between the channels will cause interleaving (IL) spurs. The clock duty error in clock signals used by sub-DACs of the time-interleaved DAC causes a dominant IL spur. For example, a DDR DAC's sampling clock with a non-50% duty cycle makes an output current of the DDR DAC has a time-dependent width, and the DDR DAC's IL spur causes an IL image of its shaped, out-of-band noise falling in a single band, degrading the signal-to-noise (SNR) performance significantly. Thus, there is a need for an innovative design for measuring and correcting an IL spur of time-interleaved DACs that act as high-speed feedback DACs in a DS ADC.

### SUMMARY

One of the objectives of the claimed invention is to provide a circuit and method for measuring and correcting an interleaving spur of at least one time-interleaved digital-to-analog converter included in a delta-sigma analog-to-digital converter.

According to a first aspect of the present invention, an exemplary measuring circuit for measuring an interleaving (IL) spur of at least one time-interleaved digital-to-analog converter (DAC) included in a delta-sigma (DS) analog-to-digital converter (ADC) is disclosed. The exemplary measuring circuit includes a dither tone generator circuit and a digital signal processing circuit. The dither tone generator circuit is configured to generate a dither tone with a pre-defined tone frequency, and inject the dither tone to the DS ADC. The digital signal processing circuit is configured to process a digital output of the DS ADC with the dither tone injected, to generate a measurement result of the IL spur that is induced by the at least one time-interleaved DAC due to the injected dither tone.

According to a second aspect of the present invention, an exemplary correction system for correcting an interleaving (IL) spur of at least one time-interleaved digital-to-analog converter (DAC) included in a delta-sigma (DS) analog-to-digital converter (ADC) is disclosed. The exemplary correction system includes a measuring circuit and a control circuit. The measuring circuit includes a dither tone generator circuit and a digital signal processing circuit. The dither tone generator circuit is configured to generate a dither tone with a pre-defined tone frequency, and inject the dither tone to the DS ADC. The digital signal processing circuit is configured to process a digital output of the DS ADC with the dither tone injected, to generate a measurement result of the IL spur that is induced by the at least one time-interleaved DAC due to the injected dither tone. The control circuit is configured to adjust IL spur correction of the at least one time-interleaved DAC according to the measurement result.

According to a third aspect of the present invention, an exemplary digital-to-analog conversion system is disclosed. The digital-to-analog conversion system includes at least one time-interleaved digital-to-analog converter (DAC) and a digital correction circuit. The digital correction circuit is configured to correct an interleaving (IL) spur of the at least one time-interleaved DAC in a digital domain.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a first correction system for correcting an IL spur of at least one time-interleaved DAC included in a DS ADC according to an embodiment of the present invention.

FIG. 2 is a diagram illustrating a current output of a DDR DAC and an IL spur resulting from DDR DAC's duty error.

FIG. 3 is a flowchart illustrating a method of measuring and correcting an IL spur of at least one time-interleaved DAC included in a DS ADC according to an embodiment of the present invention.

FIG. 4 is a diagram illustrating a second correction system for correcting an IL spur of at least one time-interleaved DAC included in a DS ADC according to an embodiment of the present invention.

FIG. 5 is a diagram illustrating a third correction system for correcting an IL spur of at least one time-interleaved DAC included in a DS ADC according to an embodiment of the present invention.

FIG. 6 is a diagram illustrating a first digital correction design according to an embodiment of the present invention.

FIG. 7 is a diagram illustrating a second digital correction design according to an embodiment of the present invention.

FIG. 8 is a diagram illustrating a digital-to-analog conversion system according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

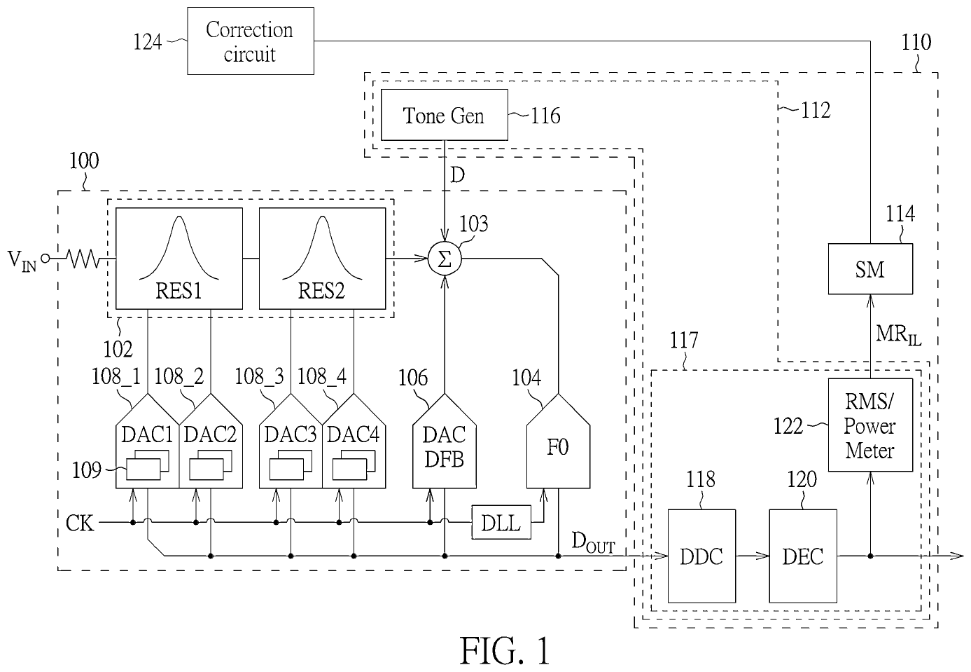

FIG. 1 is a diagram illustrating a first correction system for correcting an IL spur of at least one time-interleaved DAC included in a DS ADC according to an embodiment of the present invention. In this embodiment, a CTDS ADC 100 includes a resonator-based loop filter 102, a summation circuit 103, a quantizer (labeled by “F0”) 104, a direct feedback DAC (labeled by “DAC DFB”) 106, and a plurality of high-speed feedback DACs (labeled by “DAC1”, “DAC2”, “DAC3”, “DAC4”) 108_1, 108_2, 108_3, 108_4. For example, the CTDS ADC 100 may be a 4th-order band-pass CTDS ADC, the resonator-based loop filter 102 may be configured to act as a band-pass filter that includes two resonators (e.g., active-RC resonators) RES1 and RES2, the quantizer 104 may be a time-interleaved Flash ADC that includes a plurality of sub-ADCs, and the high-speed feedback DACs 108_1-108_4 may be time-interleaved DACs each including a plurality of sub-DACs 109. For better comprehension of technical features of the present invention, the following assumes that the time-interleaved DAC is a DDR DAC consisting of two sub-DACs used to provide an odd analog output (current) and an even analog output (current) alternatingly in each clock cycle of a sampling clock CK. In addition, the time-interleaved Flash ADC may include two sub-ADCs that are clocked to output an odd data stream and an even data stream alternatingly in each clock cycle. The high-speed feedback DACs 108_1-108_4 are clocked by the sampling clock CK, and the quantizer 104 is clocked by a sampling clock that is generated from a delay-locked loop (DLL). Since the present invention is focused on the correction system 110 that supports the proposed IL spur measurement and correction scheme and a skilled artisan can readily understand principles of the CTDS ADC 100, further description of the CTDS ADC 100 is omitted here for brevity.

In this embodiment, the correction system 110 includes a measuring circuit 112 and a control circuit (labeled by “SM”) 114. The control circuit 114 is responsible for IL spur correction control. For example, the control circuit 114 may be a state machine (SM) implemented by firmware running on a microprocessor. In this embodiment, the control circuit 114 is configured to adjust IL spur correction of high-speed feedback DACs (e.g., DDR DACs) 108_1-108_4 that is performed at the correction circuit 124, where the correction circuit 124 may deal with the IL spur correction in an analog domain (i.e., IL spur correction is analog correction) or a digital domain (i.e., IL spur correction is digital correction), depending on actual design considerations.

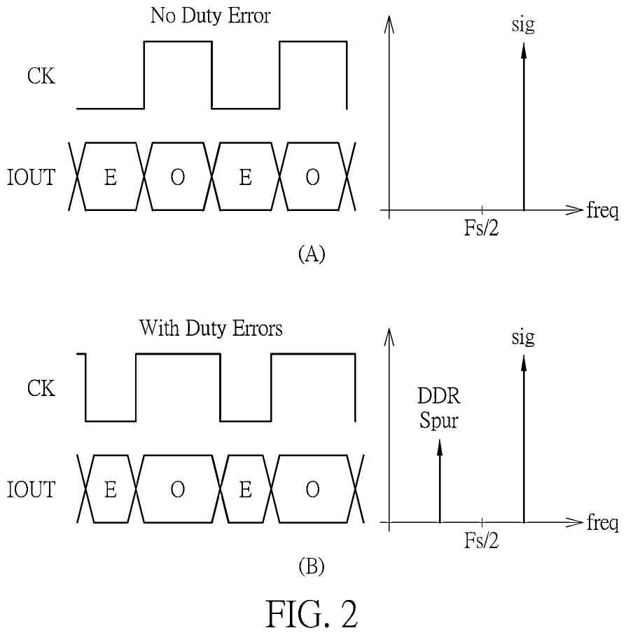

The measuring circuit 112 is responsible for IL spur measurement/quantification, and may include a dither tone generator circuit (labeled by “Tone Gen”) 116 and a digital signal processing circuit 117. The dither tone generator circuit 116 is configured to generate a dither tone D with a pre-defined tone frequency Fₜₒₙₑ, and inject the dither tone D to the CTDS ADC 100. The pre-defined tone frequency Fₜₒₙₑ is selected based on a known relation between a signal frequency and an IL spur/image frequency. FIG. 2 is a diagram illustrating an output IOUT of a DDR DAC and an IL spur resulting from DDR DAC's duty error. When the sampling clock CK has no duty error (i.e., duty cycle=50%), no IL spur/image is produced by the DDR DAC, as illustrated in sub-diagram (A) of FIG. 2. However, when the sampling clock CK has a non-50% duty cycle, the duty error (current) is produced as an image at

$$\frac{Fs}{2} \pm Fsig ,$$

where Fs is the sampling rate of the DDR DAC that is twice the clock rate Fck of the sampling clock CK (i.e., Fs=2*Fck), and Fsig is the frequency of the input signal of the DDR DAC.

In one exemplary implementation, the proposed IL spur measurement and correction scheme may operate under a foreground calibration mode. Hence, the DS ADC 100 is offline (i.e., an analog input VIN from a preceding circuit is disconnected from an input node of CTDS ADC 100) during a period in which the dither tone Dis injected to the CTDS ADC 100, and the IL spur that is induced by the high-speed feedback DACs (e. g., DDR DACs) 108_1-108_4 due to the injected dither tone D is at an in-band frequency (e.g., IL spur is induced at a frequency within a signal band centered at f0). In some embodiments of the present invention, the pre-defined tone frequency Fₜₒₙₑ may be set by

$$\frac{Fs}{2} - f 0.$$

For example, f0=2 GHz, Fs=17.28 GS/s,

$$\frac{Fs}{2} = Fck = 8 .$$

64 GHZ, and Fₜₒₙₑ=6.64 GHz. However, this is for illustrative purposes only, and is not meant to be a limitation of the present invention. In practice, the pre-defined tone frequency Fₜₒₙₑ may be set by any out-of-band frequency as long as the duty-error-induced in-band IL spur tone can be monitored by the digital signal processing circuit 117.

In another exemplary implementation, the proposed IL spur measurement and correction scheme may operate under a background calibration mode. Hence, the DS ADC 100 is online (i.e., an analog input VIN from a preceding circuit is fed into an input node of CTDS ADC 100) during a period in which the dither tone D is injected to the CTDS ADC 100, and the IL spur that is induced by the high-speed feedback DACs (e.g., DDR DACs) 108_1-108_4 due to the injected dither tone D is at an out-of-band frequency (e.g., the IL spur is induced at a frequency within an adjacent band that is outside a signal band with bandwidth BW=320 MHz and band center f0=2 GHZ). Hence, the pre-defined tone frequency Fₜₒₙₑ may be set by

$$\frac{Fs}{2} - f 1.$$

For example, f1=2.2 GHz>f0, Fs=17.28 GS/s,

$$\frac{Fs}{2} = Fck = 8 .$$

64 GHZ, and Fₜₒₙₑ=6.44 GHZ. The correction system 110 can perform IL spur measurement without interfering with normal signal processing. However, this is for illustrative purposes only, and is not meant to be a limitation of the present invention. In practice, the pre-defined tone frequency Fₜₒₙₑ may be set by any out-of-band frequency as long as the duty-error-induced out-of-band IL spur tone can be monitored by the digital signal processing circuit 117.

In this embodiment, the dither tone D is an analog tone that is injected to the summation circuit 103 located at an input node of the quantizer (e.g., time-interleaved Flash ADC) 104. For example, the dither tone D may be a square wave or a sine wave, depending on actual design considerations.

The digital signal processing circuit 117 is configured to process a digital output Dour of the CTDS ADC 100 with the dither tone D injected, to generate a measurement result MRIL of the IL spur/image that is induced by high-speed feedback DACs (e.g., DDR DACS) 108_1-108_4 due to the injected dither tone D. In this embodiment, the digital signal processing circuit 117 may include a digital down-conversion circuit (labeled by “DDC”) 118, a decimation filter (labeled by “DEC”) 120, and a power estimation circuit (labeled by “RMS/Power Meter”) 122. If the proposed IL spur measurement and correction scheme is enabled under a foreground calibration mode, the digital down-conversion circuit 118 and decimation filter 120 used by a receiver (RX) ADC system can be re-used by the correction system 110. That is, the digital down-conversion circuit 118 and decimation filter 120 in the RX digital front-end (DFE) can be used for normal reception and re-used for foreground calibration. If the proposed IL spur measurement and correction scheme is enabled under a background calibration mode, the digital down-conversion circuit 118 and decimation filter 120 are extra circuits added to the RX ADC system. That is, the RX DFE has one set of digital down-conversion circuit and decimation filter enabled for normal reception during a period in which the digital down-conversion circuit 118 and decimation filter 120 are enabled for background calibration.

In this embodiment, the resonator-based loop filter 102 is configured to act as a band-pass filter. Since the CTDS ADC 100 is a band-pass ADC, the digital down-conversion circuit 118 may be used to shift the bandwidth of interest to baseband and discard the rest of data, allowing more intensive processing to be performed on the signal of interest. The complex signal output (I+Q) of the digital down-conversion circuit 118 is processed by the decimation filter 120. The decimation filter 120 is used to implement down-sampling and filtering. The power estimation circuit 122 is used to observe root mean square (RMS) power of a decimated complex signal over a defined bandwidth (e.g., BW=80 MHz) in or near the signal band (which is achieved through digital down-conversion and decimation filtering). If the proposed IL spur measurement and correction scheme is enabled under a foreground calibration mode, the IL spur can be induced at the in-band frequency (e.g., band-center frequency f0), and the decimated, mixed-downed energy near the in-band frequency at which the IL spur is intentionally induced due to the injected dither tone D is monitored by the power estimation circuit 122. If the proposed IL spur measurement and correction scheme is enabled under a background calibration mode, the IL spur can be induced at the out-of-band frequency, and the decimated, mixed-downed energy near the out-of-band frequency at which the IL spur is intentionally induced due to the injected dither tone D is monitored by the power estimation circuit 122.

The control circuit (e.g., state machine) 114 is configured to adjust IL spur correction of the high-speed feedback DACs (e. g., DDR DACs) 108_1-108_4 according to the measurement result MRIL. The measurement result MRIL is used to provide quantification of DDR DAC'S IL spur performance. If the duty error is small, applying the dither tone D at the pre-defined tone frequency or not will not cause any difference in the RMS reading indicated by the measurement result MRIL. If the duty error is large, applying the dither tone D at the pre-defined tone frequency will result in a higher RMS reading indicated by the measurement result MRIL. The correction circuit 124 is capable of correcting the IL spur caused by the duty error through analog hardware or digital hardware. Hence, the control circuit 114 instructs the correction circuit 124 to adjust the IL spur correction of the high-speed feedback DACs (e.g., DDR DACs) 108_1-108_4 by comparing the RMS reading indicated by the measurement result MRIL with a pre-defined threshold. When the RMS reading is not lower than the pre-defined threshold, meaning that the RMS reading is not minimized yet, the control circuit 114 instructs the correction circuit 124 to adjust the analog/digital correction, and then the digital signal processing circuit 117 processes the digital output Dour of the CTDS ADC 100 with the dither tone D injected, to generate another measurement result MRIL of the high-speed feedback DACs (e. g., DDR DACs) 108_1-108_4. The control circuit 114 does not stop instructing the correction circuit 124 to adjust the analog/digital correction until the RMS reading is minimized (i.e., the RMS reading is lower than the pre-defined threshold).

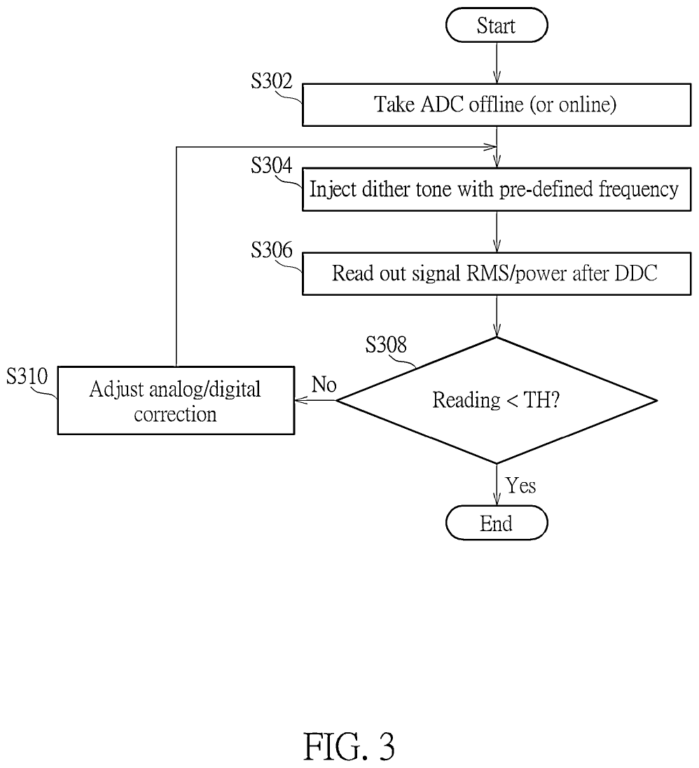

FIG. 3 is a flowchart illustrating a method of measuring and correcting an IL spur of at least one time-interleaved DAC included in a DS ADC according to an embodiment of the present invention. Provided that the result is substantially the same, the steps are not required to be executed in the exact order shown in FIG. 3. An IL spur measurement and correction procedure may be performed under a condition that the CTDS ADC 100 is offline or online (step S302). In other words, when the proposed IL spur measurement and correction scheme operates under a foreground calibration mode, there is no voltage input VIN (which may be an output of an RX analog front-end (AFE)) fed into an input node of the DS ADC 100; and when the proposed IL spur measurement and correction scheme operates under a background calibration mode, a voltage input VIN (which may be an output of an RX analog front-end (AFE)) is fed into an input node of the DS ADC 100.

At step S304, the dither tone D generated from the dither tone generator circuit 116 is injected to the summation circuit 103 for intentionally inducing an IL spur at an in-band frequency (e.g., band-center frequency f0 of the signal band) under the foreground calibration mode or an out-of-band frequency (e.g., a frequency in an adjacent band) under the background calibration mode.

At step S306, the control circuit 114 reads the measurement result MRIL (e.g., RMS power over a defined BW). At step S308, the control circuit 114 examines the measurement result MRIL (e.g., RMS power value) to detect existence of a large duty error as well as IL spur magnitude induced by the large duty error. When the reading indicated by the measurement result MRIL is not lower than a pre-defined threshold TH, the control circuit 114 instructs the correction circuit the 124 to adjust current setting of analog/digital correction. Hence, the dither tone D is injected to the summation circuit 103 again for inducing the IL spur (step S304), and the digital signal processing circuit 117 processes the digital output Dour of the CTDS ADC 100 with the dither tone D injected, to generate another measurement result MRIL (step S306). The control circuit 114 checks the measurement result MRIL again, to determine whether to instruct the correction circuit 124 to adjust its current setting of analog/digital correction. The control circuit 114 does not stop adjusting IL spur correction of the high-speed feedback DACs (e.g., DDR DACs) 108_1-108_4 until the reading indicated by the measurement result MRIL is lower than the pre-defined threshold TH. Hence, when the minimum reading is obtained by the latest IL spur correction iteration, it is determined that SNR degradation caused by DDR DAC's duty error is mitigated greatly.

Regarding the embodiment shown in FIG. 1, the dither tone D is an analog tone that is injected to an input node of the quantizer 104. However, this is for illustrative purposes only, and is not meant to be a limitation of the present invention. In practice, any means capable of adding a dither tone to induce an IL spur resulting from a duty error of time-interleaved DACs in a DS ADC can be employed by the proposed IL spur measurement and correction scheme.

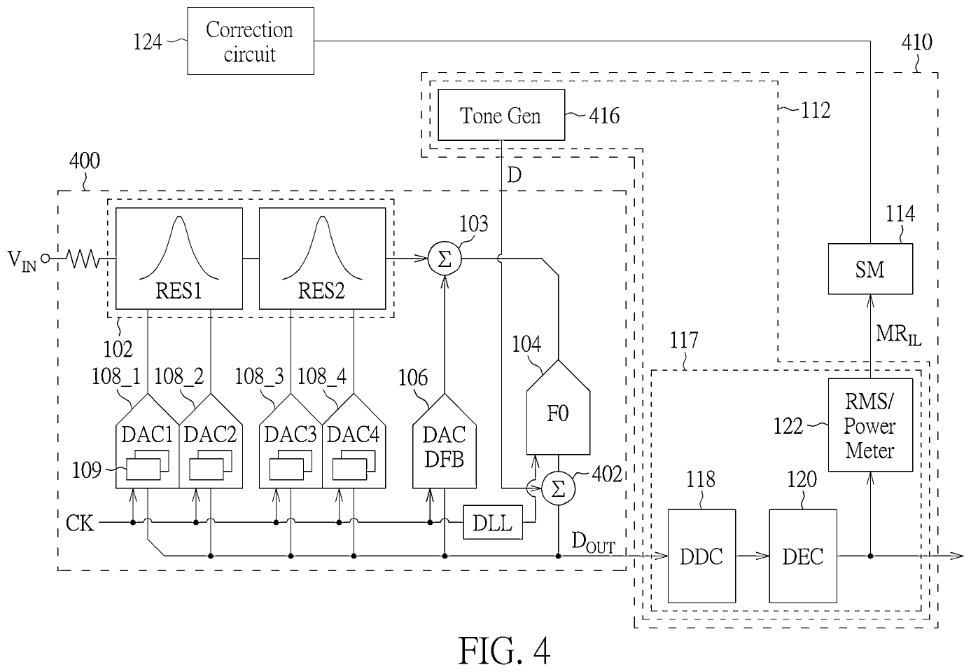

FIG. 4 is a diagram illustrating a second correction system for correcting an IL spur of at least one time-interleaved DAC included in a DS ADC according to an embodiment of the present invention. The major difference between the correction systems 110 and 410 is that the dither tone D generated from the dither tone generator circuit 416 is a digital tone that is injected to a summation circuit 402 located at an output node of the quantizer 104 of the CTDS ADC (e.g., band-pass CTDS ADC) 400.

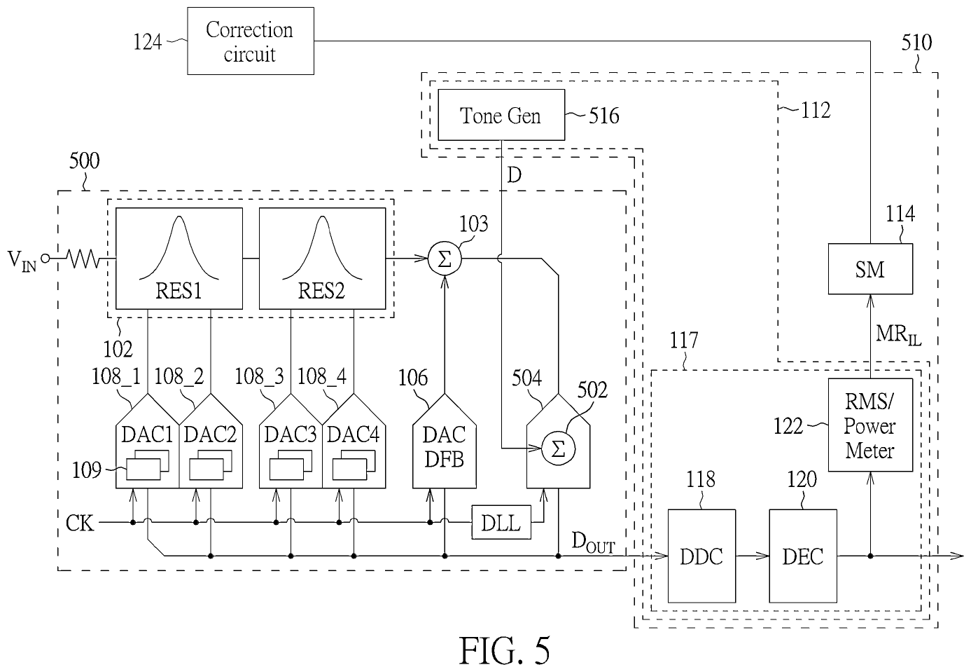

FIG. 5 is a diagram illustrating a third correction system for correcting an IL spur of at least one time-interleaved DAC included in a DS ADC according to an embodiment of the present invention. The major difference between the correction systems 110 and 510 is that the dither tone D generated from the dither tone generator circuit 516 may be a digital tone or an analog tone that is injected to a summation circuit 502 located at an internal node of the quantizer 504 of the CTDS ADC (e.g., band-pass CTDS ADC) 500. For example, the quantizer 504 may be implemented using a Flash ADC, and the internal node may be connected between internal circuit blocks of the Flash ADC.

As mentioned above, the digital signal processing circuit 117 generates the measurement result MRIL that is indicative of the magnitude of the IL spur intentionally induced by the injected dither tone D, and the control circuit 114 instructs the correction circuit 124 to adjust the IL spur correction for minimizing the IL spur energy measured at the power estimation circuit 122. The correction circuit 124 can correct the duty error and hence eliminate its negative impact either as a spur tone or a noise image. In some embodiments of the present invention, the IL spur correction may be implemented using analog correction. That is, the correction circuit 124 includes analog correction hardware for achieving the objective of minimizing the IL spur energy measured at the power estimation circuit 122. For example, the analog correction hardware may be used to adjust the sampling clock CK for reducing the duty error of the sampling clock CK.

In some embodiments of the present invention, the IL spur correction may be implemented using digital correction. The digital correction is simple, accurate, and very stable. With just common duty error, the DAC output current waveform gets modulated into “wider” or “narrower” pulses depending on the rising edge or the falling edge, as illustrated in FIG. 2. It can be corrected in a digital domain through scaling digital samples by the same amount.

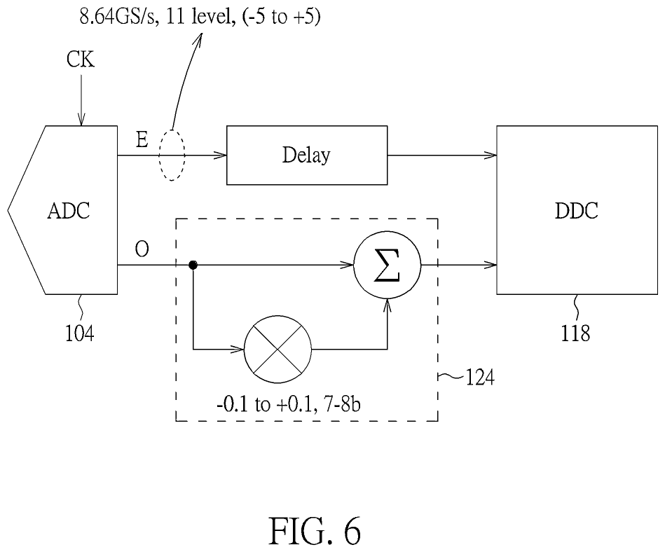

FIG. 6 is a diagram illustrating a first digital correction design according to an embodiment of the present invention. The quantizer (labeled by “ADC”) 104 may be implemented using a time-interleaved Flash ADC, and the digital output Dour may include a plurality of data streams output from a plurality of sub-ADCs included in the time-interleaved Flash ADC. The digital correction may include digital amplitude scaling of digital samples included in at least one of the plurality of data streams output from the time-interleaved Flash ADC. Assuming that each of the high-speed feedback DACs 108_1-108_4 is implemented using a DDR DAC, the digital output Dour includes an event data stream E and an odd data stream O, where each digital sample of the odd data stream O is output at the rising edge of the sampling clock CK with Fck=8.64 GHZ, and each digital sample of the even data stream E is output at the falling edge of the sampling clock CK with Fck=8.64 GHz. As shown in FIG. 6, the correction circuit 124 may be implemented using a single-tap programmable finite impulse response (PFIR) filter. The single-tap PFIR filter is used to process the odd data stream O for achieving IL spur correction in the digital domain. For example, the quantizer (e.g., Flash ADC) 104 may have 11 quantization levels (−5 to +5), and the single-tap PFIR filter may apply digital amplitude scaling (0.9 to 1.1) of digital samples included in the odd data stream O. The correction provided by the single-tap PFIR filter is very stable and power-efficient compared to the analog way of correction.

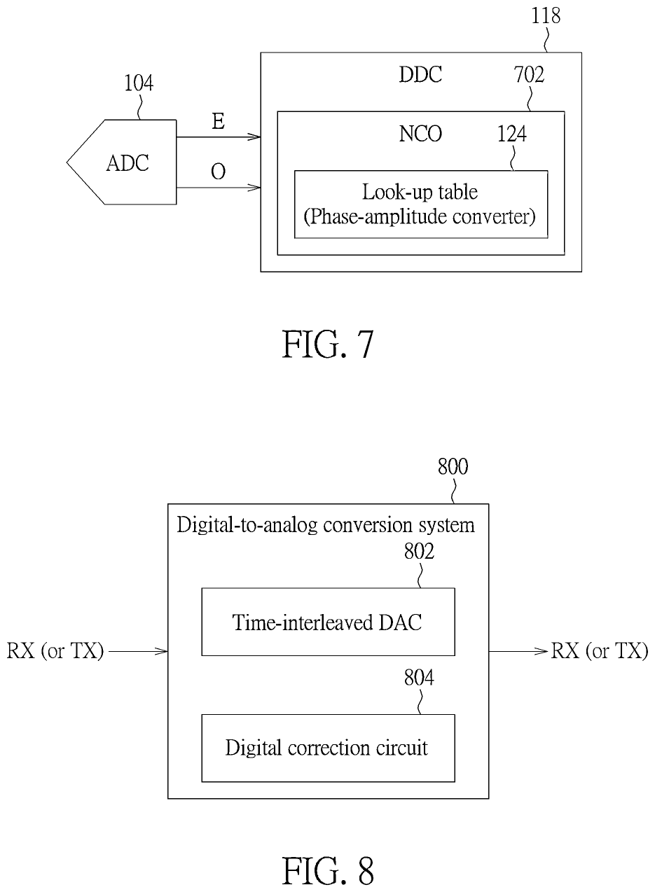

FIG. 7 is a diagram illustrating a second digital correction design according to an embodiment of the present invention. The quantizer 104 may be implemented using a time-interleaved Flash ADC, and the digital output Dour may include a plurality of data streams output from a plurality of sub-ADCs included in the time-interleaved Flash ADC. In addition, the digital down-conversion circuit 118 may include a numerically controlled oscillator (NCO) 702 and other circuit blocks (not shown). The NCO 702 is a digital signal generator which creates a discrete-time, discrete-valued representation of a sinusoidal waveform. The most common technique for implementing the NCO 702 is based on a look-up table 124. The look-up table 124 is used to store sample values of a sinusoidal signal, which are read out at appropriate time intervals to produce the sinusoidal signal. Specifically, the look-up table 124 takes an index/address and outputs an associated output sample value. This look-up table 124 is nominally filled with sample values of a full-cycle of a sinusoidal signal, such that the input address represents the associated phase for a given output value. In this way, the look-up table 124 is also known as a phase-to-amplitude converter. The digital correction includes digital amplitude scaling of sample values of a digital local oscillator (LO) signal that is generated by the NCO 702. In this embodiment, the digital amplitude scaling can be adjusted by simply updating sample values stored in the look-up table 124.

The proposed digital correction design can be used to perform IL spur correction of time-interleaved DACs in a DS ADC. However, this is for illustrative purposes only, and is not meant to be a limitation of the present invention. In practice, any time-interleaved DAC using the proposed digital correction technique for IL spur correction falls within the scope of the present invention.

FIG. 8 is a diagram illustrating a digital-to-analog conversion system according to an embodiment of the present invention. The digital-to-analog conversion system 800 includes at least one time-interleaved DAC 802 and a digital correction circuit 804. The time-interleaved DAC 802 may adopt quad-switch DAC architecture which suffers from IL spurs due to sampling clock's duty error. The digital correction circuit 804 is configured to correct IL spurs of the time-interleaved DAC 802 in a digital domain. For example, the digital correction circuit 804 may apply digital amplitude scaling to a digital bitstream for achieving IL spur correction of the time-interleaved DAC 802. In some embodiments of the present invention, the time-interleaved DAC 802 with digital IL spur correction may be employed by a wireless transmitter (TX) circuit. For example, the time-interleaved DAC 802 may act as an open-loop DAC of the TX circuit. In some embodiments of the present invention, the time-interleaved DAC 802 with digital IL spur correction may be employed by a wireless receiver (RX) circuit. For example, the time-interleaved DAC 802 may be any of the aforementioned high-speed feedback DACs 108_1-108_4 included in the DS ADC 100/400/500.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A measuring circuit for measuring an interleaving (IL) spur of at least one time-interleaved digital-to-analog converter (DAC) included in a delta-sigma (DS) analog-to-digital converter (ADC), comprising:
a dither tone generator circuit, configured to generate a dither tone with a pre-defined tone frequency, and inject the dither tone to the DS ADC; and
a digital signal processing circuit, configured to process a digital output of the DS ADC with the dither tone injected, to generate a measurement result of the IL spur that is induced by the at least one time-interleaved DAC due to the injected dither tone.

2. The measuring circuit of claim 1, wherein the DS ADC is offline during a period in which the dither tone is injected, and the IL spur is induced at an in-band frequency.

3. The measuring circuit of claim 1, wherein the DS ADC is online during a period in which the dither tone is injected, and the IL spur is induced at an out-of-band frequency.

4. The measuring circuit of claim 1, wherein the DS ADC is a continuous-time DS ADC.

5. The measuring circuit of claim 1, wherein the DS ADC is a band-pass ADC.

6. The measuring circuit of claim 1, wherein the dither tone is a digital tone.

7. The measuring circuit of claim 1, wherein the dither tone is an analog tone.

8. The measuring circuit of claim 1, wherein the dither tone is injected to an input node of a quantizer included in the DS ADC.

9. The measuring circuit of claim 1, wherein the dither tone is injected to an internal node of a quantizer included in the DS ADC.

10. The measuring circuit of claim 1, wherein the dither tone is injected to an output node of a quantizer included in the DS ADC.

11. The measuring circuit of claim 1, wherein each of the at least one time-interleaved DAC is a double-data-rate (DDR) DAC.

12. A correction system for correcting an interleaving (IL) spur of at least one time-interleaved digital-to-analog converter (DAC) included in a delta-sigma (DS) analog-to-digital converter (ADC), comprising:
a measuring circuit, comprising:
a dither tone generator circuit, configured to generate a dither tone with a pre-defined tone frequency, and inject the dither tone to the DS ADC; and
a digital signal processing circuit, configured to process a digital output of the DS ADC with the dither tone injected, to generate a measurement result of the IL spur that is induced by the at least one time-interleaved DAC due to the injected dither tone; and
a control circuit, configured to adjust IL spur correction of the at least one time-interleaved DAC according to the measurement result.

13. The correction system of claim 12, wherein the IL spur correction comprises analog correction.

14. The correction system of claim 12, wherein the IL spur correction comprises digital correction.

15. The correction system of claim 14, wherein the digital output comprises a plurality of data streams output from a plurality of sub-ADCs included in a time-interleaved ADC of the DS ADC, and the digital correction comprises digital amplitude scaling of digital samples included in at least one of the plurality of data streams.

16. The correction system of claim 14, wherein the digital output comprises a plurality of data streams output from a plurality of sub-ADCs included in a time-interleaved ADC of the DS ADC, the digital signal processing circuit comprises a digital down-conversion circuit, and the digital correction comprises digital amplitude scaling of a digital local oscillator (LO) signal generated by a numerically controlled oscillator (NCO) of the digital down-conversion circuit.

17. The correction system of claim 12, wherein the DS ADC is a continuous-time DS ADC.

18. A digital-to-analog conversion system comprising:
at least one time-interleaved digital-to-analog converter (DAC); and
a digital correction circuit, configured to correct an interleaving (IL) spur of the at least one time-interleaved DAC in a digital domain.

19. The digital-to-analog conversion system of claim 18, wherein the at least one time-interleaved DAC is employed by a wireless transmitter (TX) circuit.

20. The digital-to-analog conversion system of claim 18, wherein the at least one time-interleaved DAC is employed by a wireless receiver (RX) circuit.
